(19) United States
(12) Patent Application Publication
(10) Pub. No.: US 2026/0136583 A1
(43) Pub. Date: May 14, 2026

(54) SEMICONDUCTOR DEVICES AND METHODS OF MANUFACTURING THEREOF

(71) Applicant: Taiwan Semiconductor Manufacturing Company, Ltd., Hsinchu (TW)

(72) Inventors: Ke-Jing Ku, New Taipei City (TW); Ru-Shang Hsiao, Hsinchu City (TW); Che-Ting Chu, Hsinchu City (TW)

(73) Assignee: Taiwan Semiconductor Manufacturing Company, Ltd., Hsinchu (TW)

(21) Appl. No.: 19/098,350

(22) Filed: Apr. 2, 2025

Related U.S. Application Data
(60) Provisional application No. 63/720,271, filed on Nov. 14, 2024.

(51) Int. Cl. H10D 30/00; H10D 30/01

(52) U.S. Cl. CPC H10D 30/509; H10D 30/0196; H10D 30/508

(57) ABSTRACT

A semiconductor device comprises a plurality of nanostructures, a first epitaxial structure, a second epitaxial structure, a gate structure, a plurality of inner spacers, and a plurality of silicon-based cap layers. The plurality of nanostructures can be disposed over and spaced from one another. The first epitaxial structure and a second epitaxial structure can be coupled to ends of each of the plurality of nanostructures, respectively. The gate structure wraps around each of the plurality of nanostructures. Each of the plurality of inner spacers can be interposed between a corresponding section of the gate structure and the first or second epitaxial structure. Each of the silicon-based cap layers can be disposed above or below a corresponding one of the plurality of inner spacers.

### CROSS-REFERENCE TO RELATED APPLICATION

This application claims priority to and the benefit of U.S. Provisional Application Number 63/720,271, filed Nov. 14, 2024, entitled “INNER SPACER WITH SEMICONDUCTOR CAP LAYER,” which is incorporated herein by reference in its entirety for all purposes.

### BACKGROUND

The present disclosure generally relates to semiconductor devices, and particularly to methods of making a non-planar transistor device. The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a gate-all-around (GAA) field-effect-transistor (FET) device, in accordance with some embodiments.

FIG. 2 illustrates a flow chart of an example method for making a non-planar transistor device, in accordance with some embodiments.

FIGS. 3, 4, 5, 6, 7, 8, 9, 10, 11, 12, 13, and 14 illustrate cross-sectional views of an example GAA FET device (or a portion of the example GAA FET device) during various fabrication stages, made by the method of FIG. 2, in accordance with some embodiments.

FIG. 15 illustrates a cross-sectional view of a gate-all-around (GAA) field-effect-transistor (FET) device, in accordance with some embodiments.

FIG. 16 illustrates a cross-sectional view of a gate-all-around (GAA) field-effect-transistor (FET) device, in accordance with some embodiments.

FIG. 17 illustrates a cross-sectional view of a gate-all-around (GAA) field-effect-transistor (FET) device, in accordance with some embodiments.

FIG. 18 illustrates a cross-sectional view of a gate-all-around (GAA) field-effect-transistor (FET) device, in accordance with some embodiments.

FIG. 19 illustrates a cross-sectional view of a gate-all-around (GAA) field-effect-transistor (FET) device, in accordance with some embodiments.

FIG. 20 illustrates a cross-sectional view of a gate-all-around (GAA) field-effect-transistor (FET) device, in accordance with some embodiments.

FIG. 21 illustrates a cross-sectional view of a gate-all-around (GAA) field-effect-transistor (FET) device, in accordance with some embodiments.

FIG. 22 illustrates a cross-sectional view of a gate-all-around (GAA) field-effect-transistor (FET) device, in accordance with some embodiments.

FIG. 23 illustrates an example performance of a gate-all-around (GAA) field-effect-transistor (FET) device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In gate-all-around (GAA) approaches, a nitridation process, such as NH₃ pre-treatment, can be performed before forming an inner spacer. In some embodiments, stressor epitaxial growth (EPI) can be employed to induce channel strain, with materials like SiGe:B used in PMOS devices for compressive strain or SiP:P used in NMOS devices for tensile strain. The boron (B) and phosphorus (P) dopants can diffuse into a silicon nanosheet to establish a junction overlap, thereby enhancing device performance. However, the nitrogen (N) introduced during the nitridation process can trap these dopants, preventing their diffusion (e.g., B or P) into the silicon nanosheet. This effect results in junction under-overlap, which can negatively impact the GAA device's electrical characteristics.

In the present disclosure, a silicon (Si) cap layer can be deposited prior to the NH₃ treatment. The Si cap layer can function as a channel, allowing boron (B) and phosphorus (P) dopants to diffuse into the silicon nanosheet and enhance the junction overlap in the semiconductor device. The dimensions of the Si cap layer and the stressor epitaxial growth (EPI) are carefully defined relative to the inner spacer (INSP) and the silicon nanosheet. Various shapes of the Si cap layer, such as rectangular, triangular, trapezoidal, and elliptical geometries, are described, along with considerations for dimension variations. These design parameters are crucial for optimizing device performance and addressing process variability.

The present disclosure provides various embodiments of a semiconductor device comprising a plurality of nanostructures, a first epitaxial structure, a second epitaxial structure, a gate structure, a plurality of inner spacers, and a plurality of pairs of silicon-based cap layers. The plurality of nanostructures can be vertically spaced from one another. The first epitaxial structure and a second epitaxial structure can be coupled to ends of each of the plurality of nanostructures, respectively. The gate structure wraps around each of the plurality of nanostructures. Each of the plurality of inner spacers can be interposed between a corresponding section of the gate structure and the first or second epitaxial structure. Each of the pairs of silicon-based cap layers can be disposed above and below a corresponding one of the plurality of inner spacers, respectively.

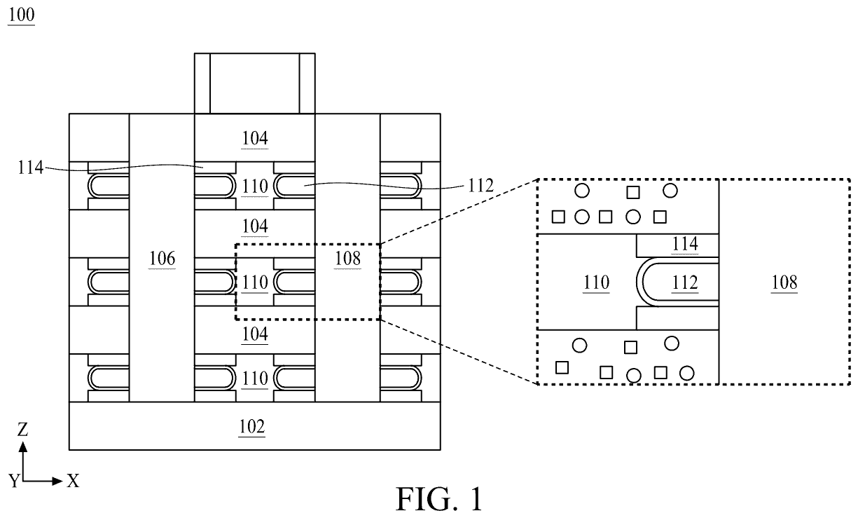

FIG. 1 illustrates a cross-sectional view of a gate-all-around (GAA) field-effect-transistor (FET) device 100, in accordance with some embodiments. The GAA FET device 100 includes a substrate 102, a plurality of nanostructures 104, a first epitaxial structure 106, a second epitaxial structure 108, a gate structure 110, a plurality of inner spacers 112, and a plurality of pairs of silicon-based cap layers 114. The plurality of nanostructures (e.g., nanosheets, nanowires, etc.) 104 can be formed above the substrate 102. The plurality of nanostructures 104 are vertically separated from one another. The gate structure 110 wraps around each of the nanostructures 104 (e.g., a full perimeter of each of the nanostructures 104). In some embodiments, source/drain structures can be disposed on opposing sides of the gate structure 110.

FIG. 1 depicts a simplified GAA FET device, and thus, it should be understood that one or more features of a completed GAA FET device may not be shown in FIG. 1. The plurality of nanostructures 104 may extend along a first lateral direction (e.g., in the X direction). The plurality of nanostructures can be vertically spaced from one another (e.g., in the Z direction). The first epitaxial structure 106 and the second epitaxial structure 108 can be coupled to ends of each of the plurality of nanostructures 104, respectively. The gate structure 110 may extend along a second lateral direction (e.g., in the Y direction) perpendicular to the first lateral direction. The gate structure 110 may wrap around each of the plurality of nanostructures 104. Each of the plurality of inner spacers 112 can be interposed between a corresponding section of the gate structure 110 and the first 106 or second epitaxial structure 108. Each of the pairs of silicon-based cap layers 114 can be disposed above and below a corresponding one of the plurality of inner spacers 112, respectively.

In some embodiments, each of the pairs of silicon-based cap layers 114 can be interposed between the corresponding section of the gate structure 110 and the first 106 or second epitaxial structure 108. In some embodiments, the silicon-based cap layers 114 may each include silicon, silicon germanium, or silicon doped with phosphorus. In some embodiments, the plurality of nanostructures 104 may include silicon. In some embodiments, each of the pairs of silicon-based cap layers 114 may have a pair of profiles symmetric to each other with respect to the corresponding inner spacer 112. In some embodiments, the profiles may each include a rectangular shape, a trapezoidal shape, a triangular shape, or an elliptical shape.

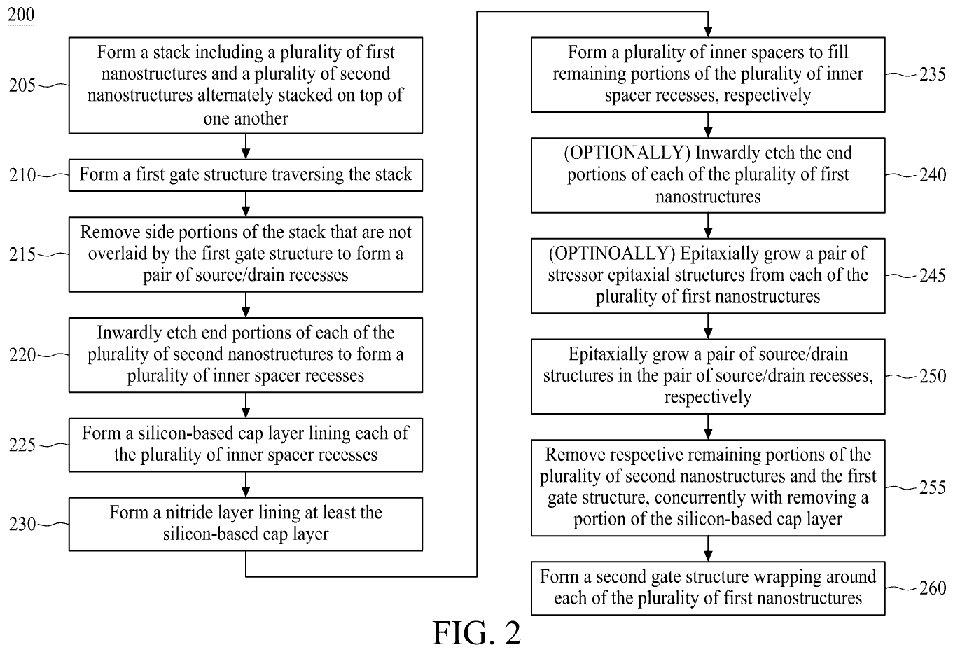

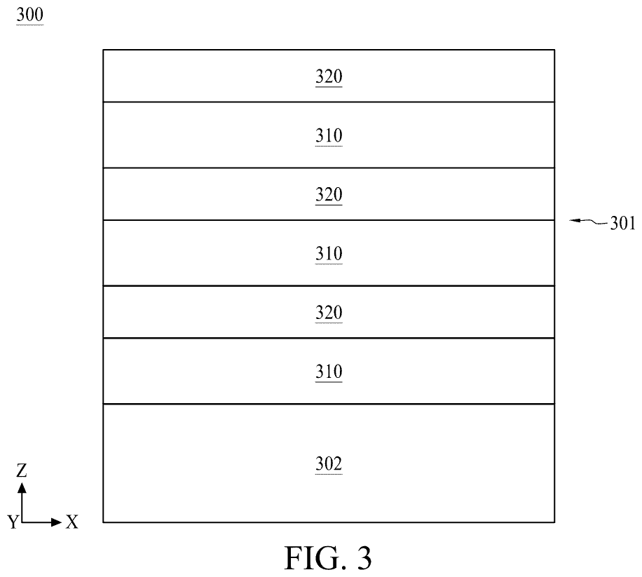

FIG. 2 illustrates a flowchart of a method 200 to form a non-planar transistor device, according to one or more embodiments of the present disclosure. For example, at least some of the operations (or steps) of the method 200 can be used to form a FinFET device, a GAA FET device (e.g., GAA FET device 100), a nanosheet transistor device, a nanowire transistor device, a vertical transistor device, a gate-all-around (GAA) transistor device, or the like. It is noted that the method 200 is merely an example, and is not intended to limit the present disclosure. Accordingly, it is understood that additional operations may be provided before, during, and after the method 200 of FIG. 2, and that some other operations may only be briefly described herein. In some embodiments, operations of the method 200 may be associated with cross-sectional views of an example GAA FET device at various fabrication stages as shown in FIGS. 3, 4, 5, 6, 7, 8, 9, 10, 11, 12, 13, 14, 15, and 16, respectively, which will be discussed in further detail below.

In brief overview, the method 200 starts with operation of forming a stack including a plurality of first nanostructures and a plurality of second nanostructures alternately stacked on top of one another. The method 200 continues to operation 210 of forming a first gate structure traversing the stack. The method 200 continues to operation 215 of removing side portions of the stack that are not overlaid by the first gate structure to form a pair of source/drain recesses. The method 200 continues to operation 220 of inwardly etching the end portions of each of the plurality of second nanostructures to form a plurality of inner spacer recesses. The method 200 continues to operation 225 of forming a silicon-based cap layer lining each of the plurality of inner spacer recesses. The method 200 continues to operation 230 of forming a nitride layer lining at least the silicon-based cap layer. The method 200 continues to operation 235 of forming a plurality of inner spacers to fill remaining portions of the plurality of inner spacer recesses, respectively. Optionally, the method 200 continues to operation 240 of inwardly etching the end portions of each of the plurality of first nanostructures. Optionally, the method 200 continues to operation 245 of epitaxially growing a pair of stressor epitaxial structures from each of the plurality of first nanostructures. The method 200 continues to operation 250 of epitaxially growing a pair of source/drain structures in the pair of source/drain recesses, respectively. The method 200 continues to operation 255 of removing respective remaining portions of the plurality of second nanostructures and the first gate structure, concurrently with removing a portion of the silicon-based cap layer. The method 200 continues to operation 260 of forming a second gate structure wrapping around each of the plurality of first nanostructures.

As mentioned above, FIGS. 3-16 each illustrate, in a cross-sectional view, a portion of a GAA FET device 300 at various fabrication stages of the method 200 of FIG. 2. The GAA FET device 300 is similar to the GAA FET device 100 shown in FIG. 1, but with certain features/structures/regions not shown, for the purposes of brevity. It should be understood the GAA FET device 300 may further include a number of other devices (not shown in the following figures) such as inductors, fuses, capacitors, coils, etc., while remaining within the scope of the present disclosure.

Corresponding to operation 205 of FIG. 2, FIG. 3 is a cross-sectional view of the GAA FET device 300 including a semiconductor substrate 302 at one of the various stages of fabrication. The substrate 302 may be a semiconductor substrate, such as a bulk semiconductor, a semiconductor-on-insulator (SOI) substrate, or the like, which may be doped (e.g., with a p-type or an n-type dopant) or undoped. The substrate 302 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 302 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

In FIG. 3, the GAA FET device 300 may include a number of first nanostructures/semiconductor layers 310 and a number of second nanostructures/semiconductor layers 320 formed on the substrate 302 at one of the various stages of fabrication. Still corresponding to operation 210 of FIG. 2, FIG. 3 is a cross-sectional view of the GAA FET device 300 including a different number of the first semiconductor layers 310 and the same number of second semiconductor layers 320 formed on the substrate 302 at one of the various stages of fabrication.

Referring to FIG. 3, the first nanostructures/semiconductor layers 310 and the second nanostructures/semiconductor layers 320 are alternatingly disposed on top of one another (e.g., along the Z direction) to form a stack. Each of the plurality of first and second nanostructures may extend along a first lateral direction (e.g., in the X direction). For example, one of the second semiconductor layers 320 is disposed over one of the first semiconductor layers 310 then another one of the first semiconductor layers 320 is disposed over the second semiconductor layer 310, so on and so forth.

The stack may include any number of alternately disposed first and second semiconductor layers 310 and 320, respectively. For example in FIG. 3, the stack includes 3 first semiconductor layers 310, with 3 second semiconductor layers 320 alternatingly disposed therebetween and with one of the second semiconductor layer 320 being the topmost semiconductor layer. It should be understood that the GAA FET device 300 can include any number of first semiconductor layers and any number of second semiconductor layers, with either one of the first or second semiconductor layers being the topmost semiconductor layer, while remaining within the scope of the present disclosure. Thus, in most of the following discussion, the stack shown in FIG. 3 will be used as a representative example.

The semiconductor layers 310 and 320 may have respective different thicknesses. Further, the first semiconductor layers 310 may have different thicknesses from one layer to another layer. The second semiconductor layers 320 may have different thicknesses from one layer to another layer. The thickness of each of the semiconductor layers 310 and 320 may range from few nanometers to few tens of nanometers. The first layer of the stack may be thicker than other semiconductor layers 310 and 320. In some embodiments, each of the first semiconductor layers 310 has a thickness ranging from about 5 nanometers (nm) to about 20 nm, and each of the second semiconductor layers 320 has a thickness ranging from about 5 nm to about 20 nm.

The two semiconductor layers 310 and 320 have different compositions. In various embodiments, the two semiconductor layers 310 and 320 have compositions that provide for different oxidation rates and/or different etch selectivity between the layers. In an embodiment, the first semiconductor layers 310 include silicon germanium (Si₁₋ₓGeₓ), and the second semiconductor layers 320 include silicon (Si). In some embodiments, each of the semiconductor layers 320 is silicon that may be undoped or substantially dopant-free (i.e., having an extrinsic dopant concentration from about 0 cm⁻³ to about 1×10¹⁷ cm⁻³), where for example, no intentional doping is performed when forming the layers 320 (e.g., of silicon).

In various embodiments, the semiconductor layers 320 may be intentionally doped. For example, when the GAA FET device 300 is configured in n-type (and operates in an enhancement mode), each of the semiconductor layers 420 may be silicon that is doped with a p-type dopant such as boron (B), aluminum (Al), indium (In), and gallium (Ga); and when the GAA FET device 300 is configured in p-type (and operates in an enhancement mode), each of the semiconductor layers 320 may be silicon that is doped with an n-type dopant such as phosphorus (P), arsenic (As), antimony (Sb). In another example, when the GAA FET device 300 is configured in n-type (and operates in a depletion mode), each of the semiconductor layers 420 may be silicon that is doped with an n-type dopant instead; and when the GAA FET device 300 is configured in p-type (and operates in a depletion mode), each of the semiconductor layers 320 may be silicon that is doped with a p-type dopant instead. In some embodiments, each of the semiconductor layers 310 is Si₁₋ₓGeₓ that includes less than 50% (x<0.5) Ge in molar ratio. For example, Ge may comprise about 15% to 35% of the semiconductor layers 310 of Si_{1-31 x}Geₓ in molar ratio. Furthermore, the first semiconductor layers 310 may include different compositions among them, and the second semiconductor layers 320 may include different compositions among them.

Either of the semiconductor layers 310 and 320 may include other materials, for example, a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. The materials of the semiconductor layers 310 and 320 may be chosen based on providing differing oxidation rates and/or etch selectivity.

The semiconductor layers 310 and 320 can be epitaxially grown from the semiconductor substrate 302. For example, each of the semiconductor layers 310 and 320 may be grown by a molecular beam epitaxy (MBE) process, a chemical vapor deposition (CVD) process such as a metal organic CVD (MOCVD) process, and/or other suitable epitaxial growth processes. During the epitaxial growth, the crystal structure of the semiconductor substrate 302 extends upwardly, resulting in the semiconductor layers 310 and 320 having the same crystal orientation with the semiconductor substrate 302.

Upon growing the semiconductor layers 310 and 320 on the semiconductor substrate 302 (as a stack), the stack may be patterned to form one or more fin structures (e.g., 301). Each of the fin structures is elongated along a lateral direction (e.g., the Y direction), and includes a stack of patterned semiconductor layers 310-320 interleaved with each other. The fin structure 301 is formed by patterning the semiconductor layers 310-320 and the semiconductor substrate 302 using, for example, photolithography and etching techniques. For example, a mask layer (which can include multiple layers such as, for example, a pad oxide layer and an overlying pad nitride layer) is formed over the topmost semiconductor layer (e.g., 320 in FIG. 3). The pad oxide layer may be a thin film comprising silicon oxide formed, for example, using a thermal oxidation process. The pad oxide layer may act as an adhesion layer between the topmost semiconductor layer 310 (or the semiconductor layer 320 in some other embodiments) and the overlying pad nitride layer. In some embodiments, the pad nitride layer is formed of silicon nitride, silicon oxynitride, silicon carbonitride, the like, or combinations thereof. The pad nitride layer may be formed using low-pressure chemical vapor deposition (LPCVD) or plasma enhanced chemical vapor deposition (PECVD), for example.

The mask layer may be patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer in this example, from subsequent processing steps, such as etching. For example, the photoresist material is used to pattern the pad oxide layer and pad nitride layer to form a patterned mask.

The patterned mask can be subsequently used to pattern exposed portions of the semiconductor layers 310-320 and the substrate 302 to form trenches (or openings), thereby defining the fin structures 301 between adjacent trenches. When multiple fin structures are formed, such a trench may be disposed between any adjacent ones of the fin structures. In some embodiments, the fin structure 301 is formed by etching trenches in the semiconductor layers 310-320 and substrate 302 using, for example, reactive ion etch (RIE), neutral beam etch (NBE), the like, or combinations thereof. The etch may be anisotropic. In some embodiments, the trenches may be strips (when viewed from the top) parallel to each other, and closely spaced with respect to each other. In some embodiments, the trenches may be continuous and surround the fin structure 301.

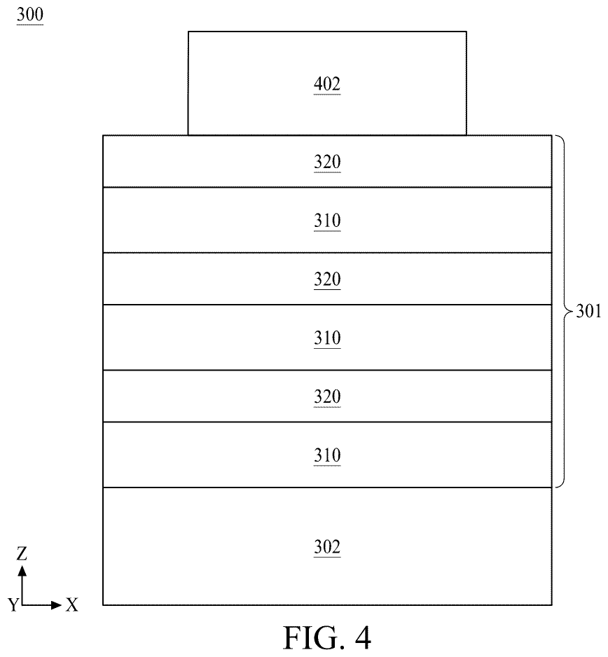

Corresponding to operation 210 of FIG. 2, FIG. 4 is a cross-sectional view of the GAA FET device 300 including a first gate structure/dummy gate structure 402, at one of the various stages of fabrication. The first gate structure/dummy gate structure 402 is formed over/traversing/straddling the fin structure 301. The first gate structure/dummy gate structure 402 can extend along a second lateral direction (e.g., the Y direction) perpendicular to the lateral direction along which the fin structure 301 extends (e.g., the X direction). The first gate structure/dummy gate structure 402 may be placed where an active (e.g., metal) gate structure is later formed, in various embodiments. In some embodiments, the first gate structure/dummy gate structure 402 is placed over a portion of fin structure 301. Such an overlaid portion of the fin structure 301 can be later formed as a conduction channel, which includes portions of the second semiconductor layers 320 and portions of the first semiconductor layers 310 that are each replaced with an active gate structure. As such, the active gate structure can wrap around each of the portions of the second semiconductor layers 320, which will be discussed in further detail below.

In some embodiments, the first gate structure/dummy gate structure 402 can include one or more Si-based or SiGe-based materials that are similar (or having similar etching rates) as the first semiconductor layers 310 such as, for example, SiGe. The first gate structure/dummy gate structure 402 may be deposited by CVD, PECVD, ALD, FCVD, or combinations thereof. Although the first gate structure/dummy gate structure 402 is shown as being formed as a single-piece in the illustrated embodiment of FIG. 4, it should be understood that the dummy gate structure 402 can be formed to have multiple portions, each of which may include respective different materials.

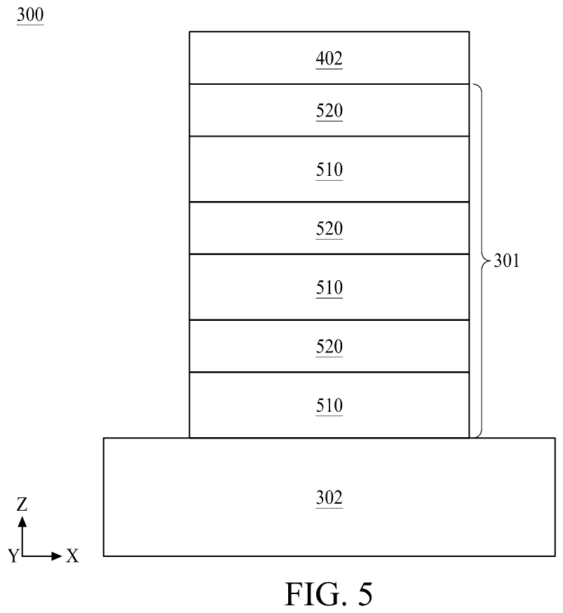

Corresponding to operation 215 of FIG. 2, FIG. 5 is a cross-sectional view of the GAA FET device 300 in which portions of the fin structure 301 that are not overlaid by the first gate structure/dummy gate structure 402 are removed, at one of the various stages of fabrication. The first gate structure/dummy gate structure 402 can serve as a mask to etch the non-overlaid portions of the fin structure 301, which results in the fin structure 301 having one or more alternatingly stacks including remaining portions of the semiconductor layers 310 and 320. As a result, along the Z direction, newly formed sidewalls of each of the fin structures 301 are aligned with sidewalls of the dummy gate structure 402. For example, in FIG. 5, semiconductor layers 510 and 520 are the remaining portions of the semiconductor layers 310 and 320 overlaid by the dummy gate structure 402, respectively. In some embodiments, the semiconductor layers 510 and 520 may sometimes be referred to as nanostructures (e.g., nanosheets) 510 and 520, respectively. In certain embodiments, the side portions of the stack that are not overlaid by the first gate structure/dummy gate structure 402 to form a pair of source/drain recesses. The source/drain recesses may expose respective end portion of the first 510 and second nanostructure 520.

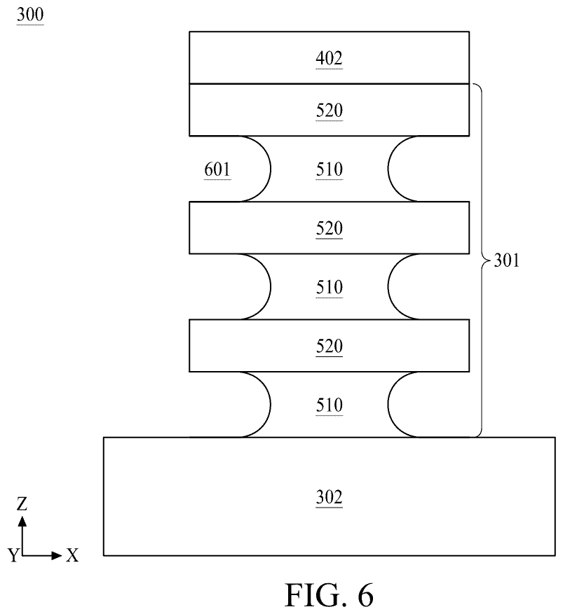

Corresponding to operation 220 of FIG. 2, FIG. 6 is a cross-sectional view of the GAA FET device 300 in which end portions of the nanostructures 510 (along the X direction) are etched, at one of the various stages of fabrication. As shown in FIG. 6, respective end portions of each of the nanostructures 510 are removed. The end portions of the nanostructures 510 can be removed (e.g., etched) using a “pull-back” process to pull the nanostructures 510 back by a pull-back distance. In an example where the semiconductor layers 520 include Si, and the semiconductor layers 510 include SiGe, the pull-back process may include a hydrogen chloride (HCI) gas isotropic etch process or a wet etching process, which etches SiGe without attacking Si. As such, the Si layers (nanostructures) 520 may remain intact during this process. Consequently, recess 601 can be formed. Further, in various embodiments, the material of the nanostructures 510 (and the material of at least the lower portion of the dummy gate structure 402) have a certain etching selectivity. In various embodiments, the difference of etching rates between the nanostructures 510 (and the dummy gate structure 402) and the nanostructures 520 may be adjusted by varying the molar ratio of Ge in the nanostructures 510, when first growing the semiconductor layers 310.

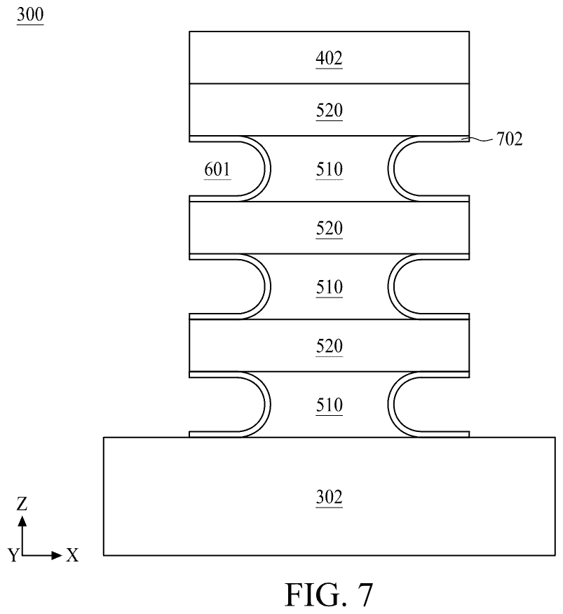

Corresponding to operation 225 of FIG. 2, FIG. 7 is a cross-sectional view of the GAA FET device 300 in which silicon-based cap layers 702 lining each of the plurality of inner spacer recesses 601 are formed, at one of the various stages of fabrication. The silicon-based cap layers 702 may include at least one of: silicon, silicon germanium, or silicon doped with phosphorus. In some embodiments, the thickness of the silicon-based cap layers 702 can range from about 1 to 5 nm. In some embodiments, the dimensions of the silicon-based cap layer 702 can be defined relative to the nanostructures 520 (e.g., silicon sheets) and inner spacers (will discuss later) to ensure precise structural and electrical characteristics. The ratio of the silicon-based cap layer critical dimension (CD) to the inner spacers CD may fall within the range of about 40% to 110%. In certain embodiments, at the epitaxial growth (EPI) side, the edge of the silicon-based cap layer 702 can be aligned such that the edge of the silicon-based cap layer 702 to an edge of the inner spacers offset in a range from about 0 to +10 nm, while the edge of the silicon-based cap layer 702 to an edge of Si sheet 520 offset in a range from about 0 to +20 nm. At the metal gate (MG) side, the edge of the Si cap layer 702 to the inner spacers offset in a range from about −10 to +10 nm. In the present disclosure, the inclusion of silicon-based cap layers 702 enables increased device junction overlap, which enhances the overall performance of the device. The silicon-based cap layers 702 can serve as a channel, allowing boron (B) and phosphorus (P) dopants to diffuse into the Si nanosheet and improve device junction overlap. Additionally, the silicon-based cap layers 702 facilitate an enlarged stressor epitaxial growth (EPI), resulting in greater strain applied to the channel. This modification alters the geometry of the GAA Si sheet and the stressor EPI compared to the original GAA configuration. These structural changes are pivotal in optimizing device characteristics and improving electrical performance. In some embodiments, the silicon-based cap layers 702 may be deposited by CVD, physical vapor deposition (PVD), ALD, and/or other suitable process.

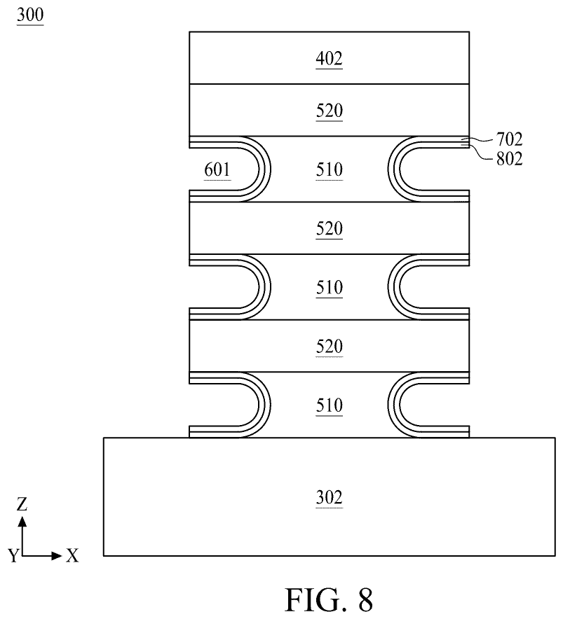

Corresponding to operation 230 of FIG. 2, FIG. 8 is a cross-sectional view of the GAA FET device 300 in which nitride layers 802 lining at least the silicon-based cap layers 702 are formed. The nitride layers 802 can be formed to line at least the silicon-based cap layers 702. In some embodiments, the nitride layers 802 can be deposited using chemical vapor deposition (CVD) or formed through a nitridation process, such as NH₃ treatment. The nitride layers 802 can serve as a protective barrier, enhancing the structural integrity of the silicon-based cap layers 702. However, excessive nitrogen incorporation can trap dopants, leading to challenges like junction under-overlap. In some embodiments, the nitride layers 802 improve the interface quality between the silicon-based cap layers 702 and other device components, such as the gate dielectric or inner spacer, by passivating surface defects and minimizing interface states. This nitride lining also contributes to better control of critical dimensions (CD) during fabrication, ensuring alignment and scalability of advanced GAA device architectures. In some embodiments, NH₃ treatment can form nitridation of interfacial oxide (SiO₂) at Si sheet/inner spacer for EPI seed layers.

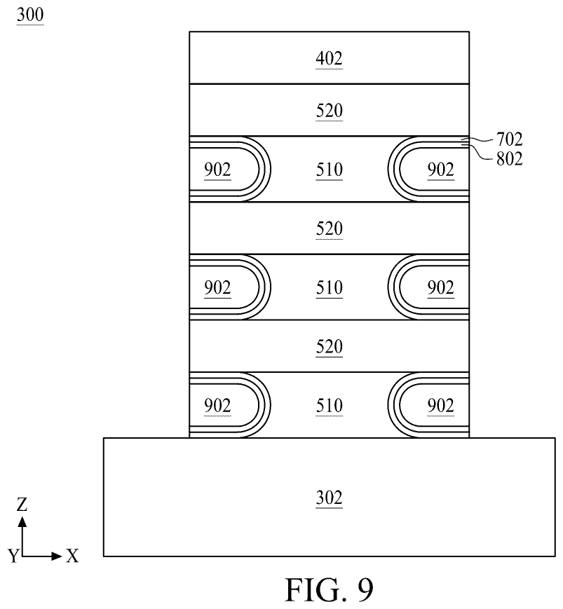

Corresponding to operation 235 of FIG. 2, FIG. 9 is a cross-sectional view of the GAA FET device 300 including an inner spacer 902, at one of the various stages of fabrication. In some embodiments, a plurality of inner spacers 902 to fill remaining portions of the plurality of inner spacer recesses 601, respectively, are formed. In some embodiments, the inner spacers 902 can be formed along respective etched ends of the nanostructures 510. Thus, the inner spacer 902 may follow the curvature-based profile of the recess 601. Each of the inner spacer 902 may be laterally aligned with a corresponding one of the nanostructures 520.

In some embodiments, the inner spacers 902 can be formed conformally by chemical vapor deposition (CVD), or by monolayer doping (MLD) of nitride followed by spacer RIE. The inner spacers 902 can be deposited using, e.g., a conformal deposition process and subsequent isotropic or anisotropic etch back to remove excess spacer material on the sidewalls of the stacks of the fin structure 301 and on a surface of the semiconductor substrate 302. The inner spacer 902 can be formed of silicon nitride, silicoboron carbonitride, silicon carbonitride, silicon carbon oxynitride, carbon-and nitride-doped silicon oxide, or any other type of dielectric material (e.g., a dielectric material having a dielectric constant k of less than about 5) appropriate to the role of forming an insulating gate sidewall spacers of transistors. In certain embodiments, during film deposition, nitride, Si-cap, and inner-spacer layers are grown on the sidewall of the Si-sheet 520. Then, a dry etching process is performed to remove the sidewall film along the Si-sheet 520. As a result, the films (nitride, Si-cap, and inner-spacer) remain beneath the Si-sheet 520.

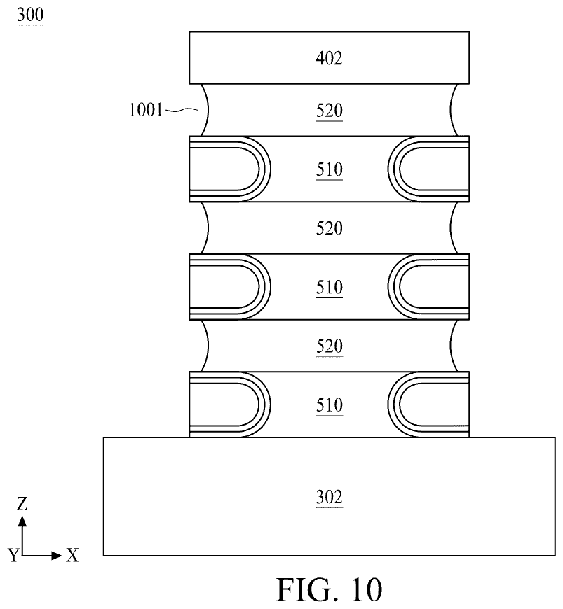

Corresponding to operation 240 (optionally) of FIG. 2, FIG. 10 is a cross-sectional view of the GAA FET device 300 in which end portions of the nanostructures 520 (along the X direction) are etched, at one of the various stages of fabrication. As shown in FIG. 10, respective end portions of each of the nanostructures 520 are removed. The end portions of the nanostructures 520 can be removed (e.g., etched) using a “pull-back” process to pull the nanostructures 520 back by a pull-back distance. In an example where the semiconductor layers 520 include Si, and the semiconductor layers 510 include SiGe, the pull-back process may include a gas isotropic etch process or a wet etching process, which etches Si without attacking inner spacers 902. As such, the inner spacers 902 may remain intact during this process. Consequently, recess 1001 can be formed. Further, in various embodiments, the material of the nanostructures 520 (and the material of at least the lower portion of the dummy gate structure 402) have a certain etching selectivity.

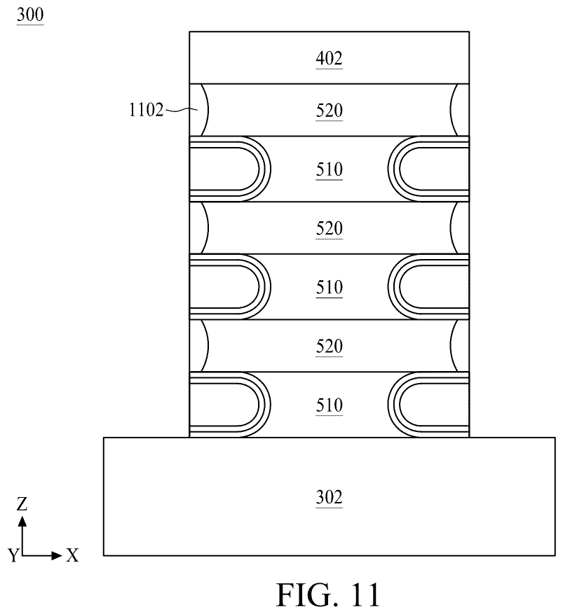

Corresponding to operation 245 (optionally) of FIG. 2, FIG. 11 is a cross-sectional view of the GAA FET device 300 including enlarged channel stressors 1102, at one of the various stages of fabrication. A pair of stressor epitaxial structures 1102 from each of the plurality of nanostructures 520 can be epitaxially grown. In some embodiments, the stressor epitaxial structures 1102 can be formed along respective etched ends of the nanostructures 520. Thus, the stressor epitaxial structures 1102 may follow the curvature-based profile of the recess 1001. Each of the stressor epitaxial structures 1102 may be laterally aligned with a corresponding one of the inner spacers 902. In some embodiments, stressor materials can be selected based on the desired strain type—silicon-germanium (SiGe) doped with boron (B) for compressive strain in PMOS devices or silicon-phosphide (SiP) doped with phosphorus (P) for tensile strain in NMOS devices. Epitaxial deposition can be performed using chemical vapor deposition (CVD), such as low-pressure CVD (LPCVD) or ultra-high vacuum CVD (UHV-CVD), with precursors like silane (SiH₄), germane (GeH₄), phosphine (PH₃), or diborane (B₂H₆). Selective epitaxy is achieved using masking techniques to limit growth to specific regions. The thickness and composition of the stressor EPI layer are carefully controlled to achieve the desired strain and minimize defects, with composition grading employed to enhance strain uniformity. Post-deposition, thermal annealing activates dopants and repairs crystal defects, while characterization techniques like X-ray diffraction (XRD) or Raman spectroscopy verify strain levels and layer quality.

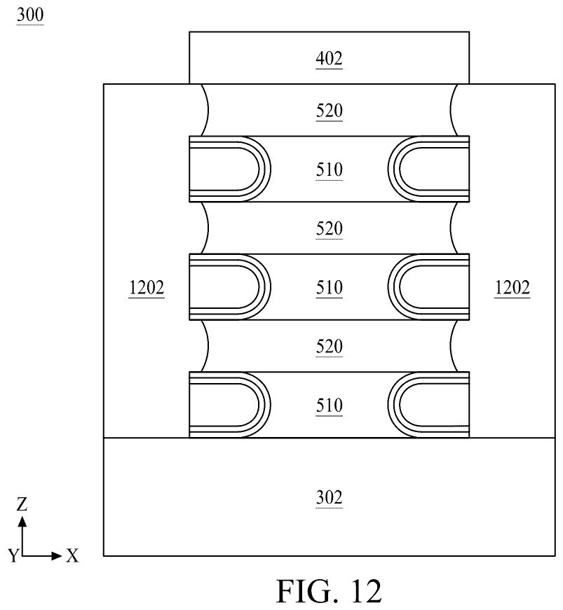

Corresponding to operation 250 of FIG. 2, FIG. 12 is a cross-sectional view of the GAA FET device 300 including a pair of source/drain structures 1202, at one of the various stages of fabrication. A pair of source/drain structures 1202 in the pair of source/drain recesses, respectively, can be epitaxially grown. In some embodiments, the pair of source/drain structures 1202 can be connected to the end portions of each of the plurality of nanostructures 520. In some embodiments, the pair of source/drain structures 1202 can be coupled to the etched end portions of each of the plurality of nanostructures 510 through the corresponding pair of stressor epitaxial structures 1102.

In some embodiments, epitaxial growth of a pair of source/drain structures 1202 involves depositing semiconductor material selectively in regions adjacent to the channel to optimize electrical performance. Chemical vapor deposition (CVD), such as low-pressure CVD (LPCVD) or ultra-high vacuum CVD (UHV-CVD), can be used for epitaxial growth. For compressive strain in PMOS devices, materials like silicon-germanium (SiGe) doped with boron (B) are deposited, while for tensile strain in NMOS devices, silicon-phosphide (SiP) doped with phosphorus (P) is used. The epitaxial growth is conducted at optimized temperatures to achieve high-quality crystalline layers while maintaining compatibility with the device structure. The thickness and lateral dimensions of the S/D structures are precisely controlled to ensure proper overlap with the channel and alignment with the gate structure.

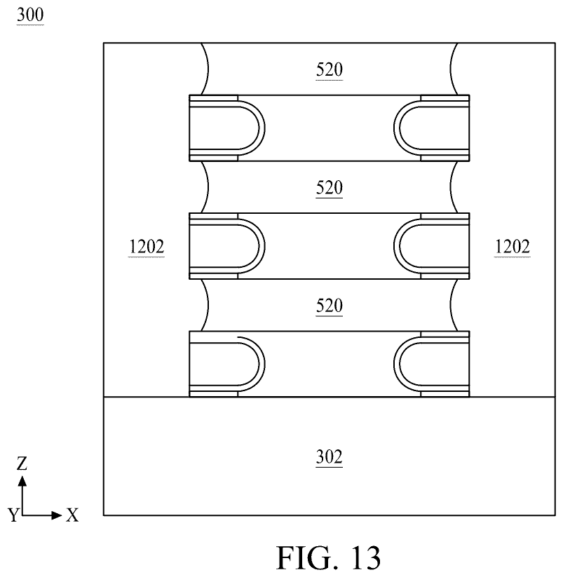

Corresponding to operation 255 of FIG. 2, FIG. 13 is a cross-sectional view of the GAA FET device 300 in which remaining portions of the plurality of nanostructures 510 and the first gate structure 402 are removed. In some embodiments, a portion of the silicon-based cap layer 702 is also removed. In various embodiments, the first gate structure 402 and the nanostructures 510 can be removed by applying a selective etch (e.g., a hydrochloric acid (HCI)), while leaving the nanostructures 520 substantially intact. After the removal of the first gate structure 402, a gate trench, exposing respective sidewalls of each of the nanostructures 520 that face the X direction, may be formed. In some embodiments, the nanostructures 510 can be removed using wet etching (e.g., NH₄OH+H₂O₂). By controlling the concentration of NH₄OH, the Si cap 702 and the nanostructures 510 can be selectively etched away, while leaving the nanostructures 520 and inner spacers 902 substantially intact. After the removal of the nanostructures 510 to further extend the gate trench, respective bottom surface and/or top surface of each of the nanostructures 520 may be exposed. Consequently, a full circumference of each of the nanostructures 520 can be exposed. In some embodiments, a portion of the silicon-based cap layer 702 facing the nanostructures 510 is also removed. Each of the pairs of silicon-based cap layers 702 may have a pair of profiles symmetric to each other with respect to the corresponding inner spacer 902. In some embodiments, the profiles may include at least one of:
a rectangular shape, a trapezoidal shape, a triangular shape, or an elliptical shape.

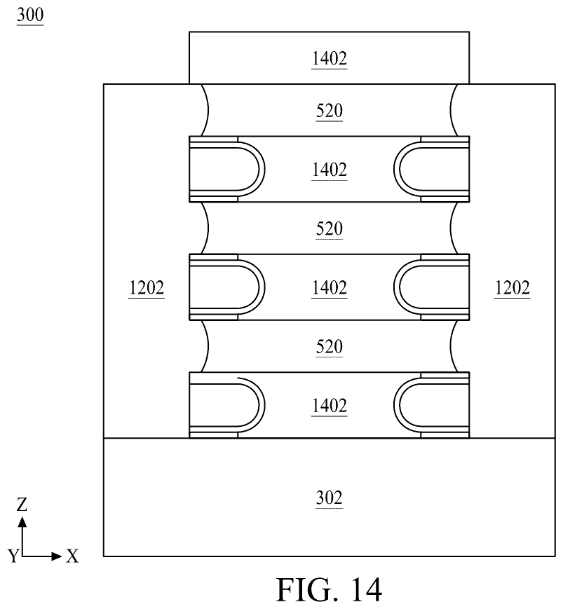

Corresponding to operation 260 of FIG. 2, FIG. 14 is a cross-sectional view of the GAA FET device 300 in which an active gate structure 1402, at one of the various stages of fabrication. A second gate structure/active or metal gate structure 1402 wrapping around each of the plurality of nanostructures 520 can be formed. The active gate structure 1402 is formed in the extended gate trench by filling with at least a gate dielectric and a gate metal. Thus, the active gate structure 1402 can inherit the dimensions and profiles of the gate trench, which are defined by the formed inner spacer 902, the removed first gate structure 402, the removed nanostructures 510, and selectively the removed portion of the silicon-based cap layers 702. The active gate structure 1402 includes a gate dielectric and a gate metal, in some embodiments. The gate dielectric can wrap around each of the nanostructures 520, e.g., the top and bottom surfaces and sidewalls facing the X direction). The gate dielectric may be formed of different high-k dielectric materials or a similar high-k dielectric material. Example high-k dielectric materials include a metal oxide or a silicate of Hf, Al, Zr, La, Mg, Ba, Ti, Pb, and combinations thereof. The gate dielectric may include a stack of multiple high-k dielectric materials. The gate dielectric can be deposited using any suitable method, including, for example, molecular beam deposition (MBD), atomic layer deposition (ALD), PECVD, and the like. In some embodiments, the gate dielectric may optionally include a substantially thin oxide (e.g., SiOₓ) layer, which may be a native oxide layer formed on the surface of each of the nanostructures 520.

The gate metal can wrap around each of the nanostructures 520 with the gate dielectric disposed therebetween. Specifically, the gate metal can include a number of gate metal sections abutted to each other along the Z direction. Each of the gate metal sections can extend not only along a horizontal plane (e.g., the plane expanded by the X direction and the Y direction), but also along a vertical direction (e.g., the Z direction). As such, two adjacent ones of the gate metal sections can adjoin together to wrap around a corresponding one of the nanostructures 520, with the gate dielectric disposed therebetween.

The gate metal may include a stack of multiple metal materials. For example, the gate metal may be a p-type work function layer, an n-type work function layer, multi-layers thereof, or combinations thereof. The work function layer may also be referred to as a work function metal. Example p-type work function metals that may include TiN, TaN, Ru, Mo, Al, WN, ZrSi₂, MoSi₂, TaSi₂, NiSi₂, WN, other suitable p-type work function materials, or combinations thereof. Example n-type work function metals that may include Ti, Ag, TaAl, TaAIC, TiAlN, TaC, TaCN, TaSiN, Mn, Zr, other suitable n-type work function materials, or combinations thereof. A work function value is associated with the material composition of the work function layer, and thus, the material of the work function layer is chosen to tune its work function value so that a target threshold voltage Vₜ is achieved in the device that is to be formed. The work function layer(s) may be deposited by CVD, physical vapor deposition (PVD), ALD, and/or other suitable process. In some embodiments, Boron (B) and phosphorus (Ph) are introduced as dopants through the source/drain epitaxial (EPI) layers to enhance the electrical performance of the GAA device. For example, in p-type EPI (P-EPI), silicon-germanium doped with boron (SiGe:B) is used to create compressive strain, while in n-type EPI (N-EPI), silicon-phosphide doped with phosphorus (SiP:Ph) is used to generate tensile strain. These doped EPI layers play a crucial role in modulating carrier mobility and improving the conductivity of the source/drain regions, thereby optimizing the overall device performance.

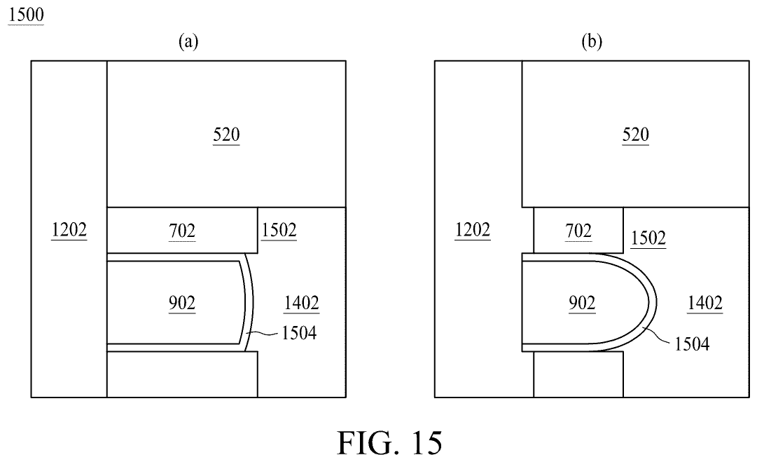

FIG. 15 illustrates a cross-sectional view of a gate-all-around (GAA) field-effect-transistor (FET) device, in accordance with some embodiments. FIG. 15 illustrates an alternative example of FIG. 1 by introducing an offset between the silicon-based cap layers 702 and the inner spacers 902. Each of the silicon-based cap layers 702 may has a first sidewall 1502. Each of the inner spacers 902 may have a second sidewall 1504. In some embodiments, a width (along X direction) of Si-based cap layer 702 is substantially same as a width/critical dimension (CD) (along X direction) of spacer 902, as shown in FIG. 15(a). In certain embodiments, the first sidewall 1502 and the second sidewall 1504 can be vertically aligned with each other. In some embodiments, the first sidewall 1502 and the second sidewall 1504 can be vertically offset from each other, as shown in FIG. 15 (b). The GAA FET device 1500 of FIG. 15 is substantially similar to the GAA FET device 100 of FIG. 1, except for offset between the silicon-based cap layers 702 and the inner spacers 902. In some embodiments, when a portion of Si-sheet 520 (at the EPI side) is laterally protruded from the edge of Si cap layer 702 (at EPI side), the epitaxial (EPI) growth may extend into the inner spacer (INSP) region. This occurs because the reduced coverage of the Si-cap layer 702 exposes part of the INSP region, allowing the epitaxial material, such as SiGe or SiP, to grow beyond the intended boundary.

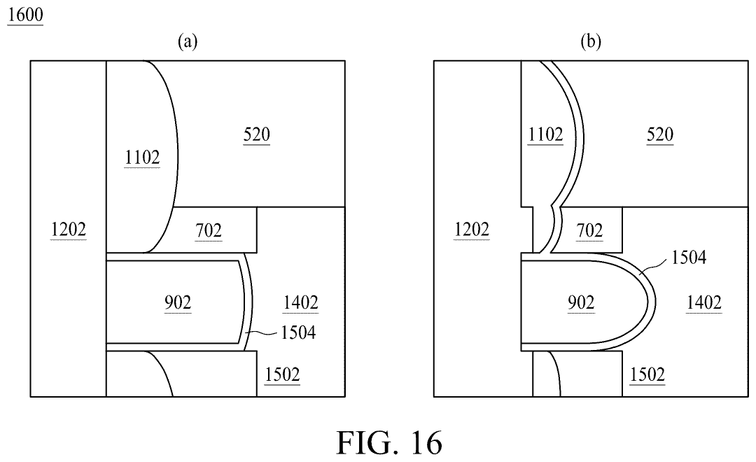

FIG. 16 illustrates a cross-sectional view of a gate-all-around (GAA) field-effect-transistor (FET) device, in accordance with some embodiments. FIG. 16 illustrates an alternative example of FIG. 1 by introducing an offset between the silicon-based cap layers 702 and the inner spacers 902, and stressor EPI 1102. Each of the silicon-based cap layers 702 may has a first sidewall 1502. Each of the inner spacers 902 may have a second sidewall 1504. In some embodiments, a width (along X direction) of Si-based cap layer 702 is substantially same as a width/critical dimension (CD) (along X direction) of spacer 902, as shown in FIG. 16(a). In certain embodiments, the first sidewall 1502 and the second sidewall 1504 can be vertically aligned with each other. In some embodiments, the first sidewall 1502 and the second sidewall 1504 can be vertically offset from each other, as shown in FIG. 16 (b). In some embodiments, the stressor epitaxial (EPI) 1102 thickness is determined as the sum of the silicon (Si) sheet 520 thickness and the Si-based cap layer 702 thickness. In some embodiments, when a portion of Si-sheet 520 (at the EPI side) is laterally protruded from the edge of Si cap layer 702 (at EPI side), as illustrated in FIG. 16(b), the stressor EPI assumes a two-step shape. This configuration allows for an enlarged channel stressor, which enhances device performance by increasing strain in the channel region. The GAA FET device 1600 of FIG. 16 is substantially similar to the GAA FET device 100 of FIG. 1, except for offset between the silicon-based cap layers 702 and the inner spacers 902, and the stressor EPI 1102. The presence of the Si-based cap layer further contributes to this effect by enabling the stressor EPI to grow larger, thereby introducing additional strain to the channel. Consequently, the geometry of the gate-all-around (GAA) Si sheet and the stressor EPI is altered compared to the original GAA configuration, offering improved electrical characteristics and enhanced device functionality.

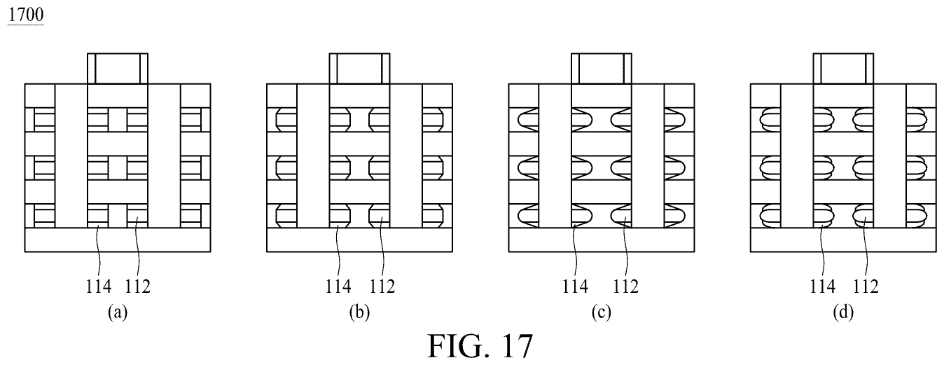

FIG. 17 illustrates a cross-sectional view of a gate-all-around (GAA) field-effect-transistor (FET) device, in accordance with some embodiments. FIG. 17 illustrates an alternative example of FIG. 1 by introducing different profiles for the silicon-based cap layers 114. In some embodiments, each of the pairs of silicon-based cap layers 114 may have a pair of profiles symmetric to each other with respect to the corresponding inner spacer 112. In some embodiments, the profiles may each include a rectangular shape (as shown in FIG. 17(a)), a trapezoidal shape (as shown in FIG. 17(b)), a triangular shape (as shown in FIG. 17(c)), or an elliptical shape (as shown in FIG. 17(d)). The silicon-based cap layers 114 can be formed over the top and bottom of the inner spacer 112 with various shapes, which can be achieved by adjusting the fabrication process. These shapes may include rectangular, triangular, trapezoidal, or elliptical configurations, depending on the desired device characteristics. The GAA FET device 1700 of FIG. 17 is substantially similar to the GAA FET device 100 of FIG. 1, except for different profiles for the silicon-based cap layers 114. In some embodiments, the presence of the Si-based cap layer plays a crucial role in enhancing the stressor epitaxial (EPI) growth, resulting in an enlarged stressor region that applies additional strain to the channel. This increased strain improves carrier mobility and overall device performance. As a result of the Si cap layer, the gate-all-around (GAA) Si-sheet geometry and the stressor EPI shape are modified compared to the original GAA structure, offering opportunities to optimize the device's electrical and mechanical properties.

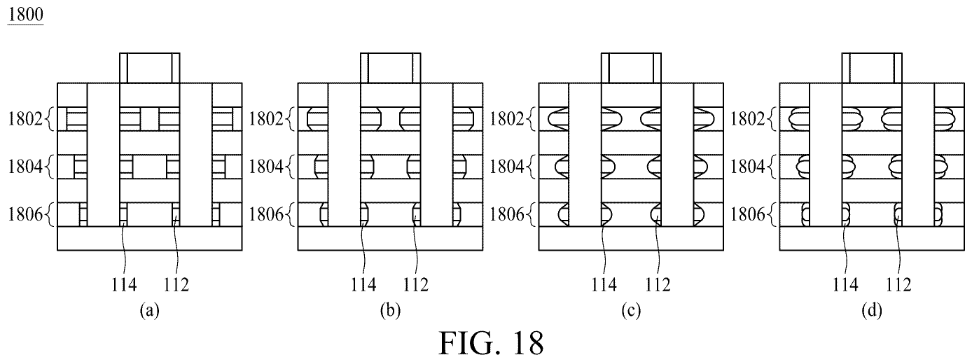

FIG. 18 illustrates a cross-sectional view of a gate-all-around (GAA) field-effect-transistor (FET) device, in accordance with some embodiments. FIG. 18 illustrates an alternative example of FIG. 1 by introducing different profiles and critical dimensions (CD) for the silicon-based cap layers 114. In some embodiments, each of the pairs of silicon-based cap layers 114 may have a pair of profiles symmetric to each other with respect to the corresponding inner spacer 112. In some embodiments, the profiles may each include a rectangular shape (as shown in FIG. 18(a)), a trapezoidal shape (as shown in FIG. 18(b)), a triangular shape (as shown in FIG. 18(c)), or an elliptical shape (as shown in FIG. 18(d)). The silicon-based cap layers 114 can be formed over the top and bottom of the inner spacer 112 with various shapes, which can be achieved by adjusting the fabrication process. In some embodiments, the critical dimension (CD) of the Si cap layer exhibits a gradient reduction from top to bottom 1802, 1804, 1806 due to process loading effects, where the second Si-cap CD 1804 is about 50% to 100% of the first Si-cap CD 1802, and the third Si-cap CD 1806 is about 50% to 100% of the second Si-cap CD 1804. This gradual reduction in CD impacts the structural profile of the Si cap layer 114. The GAA FET device 1800 of FIG. 18 is substantially similar to the GAA FET device 100 of FIG. 1, except for different profiles and critical dimensions (CD) for the silicon-based cap layers 114. The presence of the Si cap layer significantly enhances the growth of the stressor epitaxial (EPI) layer, leading to an enlarged stressor that introduces additional strain to the channel region. This added strain improves device performance by enhancing carrier mobility. Consequently, the geometry of the gate-all-around (GAA) Si sheet and the stressor EPI layer is altered compared to the original GAA configuration, offering improved electrical characteristics and optimized device functionality.

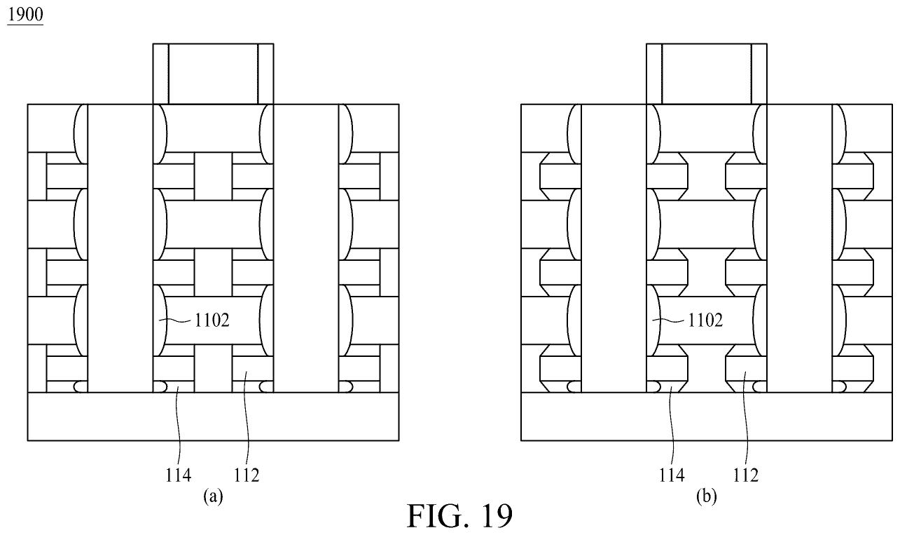

FIG. 19 illustrates a cross-sectional view of a gate-all-around (GAA) field-effect-transistor (FET) device, in accordance with some embodiments. FIG. 19 illustrates an alternative example of FIG. 1 by introducing different profiles for the silicon-based cap layers 114 and the stressor EPI 1102. In some embodiments, each of the pairs of silicon-based cap layers 114 may have a pair of profiles symmetric to each other with respect to the corresponding inner spacer 112. In some embodiments, the profiles may each include a rectangular shape (as shown in FIG. 19(a)), or a trapezoidal shape (as shown in FIG. 19(b)). The silicon-based cap layers 114 can be formed over the top and bottom of the inner spacer 112 with various shapes, which can be achieved by adjusting the fabrication process. These shapes may include rectangular, triangular, trapezoidal, or elliptical configurations, depending on the desired device characteristics. In some embodiments, the profiles of the stressor EPI 1102 may include a convex shape. The GAA FET device 1900 of FIG. 19 is substantially similar to the GAA FET device 100 of FIG. 1, except for different profiles for the silicon-based cap layers 114 and the stressor EPI 1102. In some embodiments, the presence of the Si-based cap layer plays a crucial role in enhancing the stressor epitaxial (EPI) growth, resulting in an enlarged stressor region that applies additional strain to the channel. This increased strain improves carrier mobility and overall device performance. As a result of the Si cap layer, the gate-all-around (GAA) Si-sheet geometry and the stressor EPI shape are modified compared to the original GAA structure, offering opportunities to optimize the device's electrical and mechanical properties.

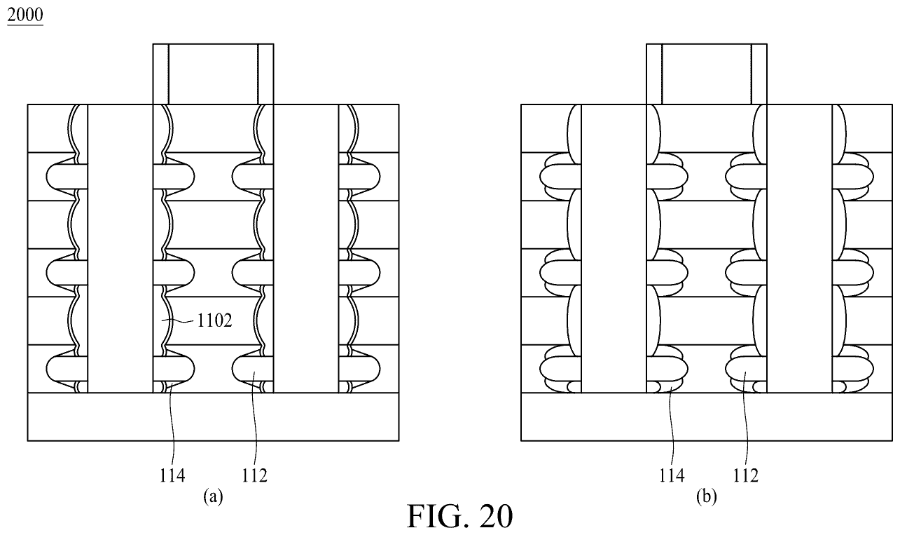

FIG. 20 illustrates a cross-sectional view of a gate-all-around (GAA) field-effect-transistor (FET) device, in accordance with some embodiments. FIG. 20 illustrates an alternative example of FIG. 1 by introducing different profiles for the silicon-based cap layers 114 and the stressor EPI 1102. In some embodiments, each of the pairs of silicon-based cap layers 114 may have a pair of profiles symmetric to each other with respect to the corresponding inner spacer 112. In some embodiments, the profiles may each include a triangle shape (as shown in FIG. 20(a)), or an ellipse shape (as shown in FIG. 20(b)). The silicon-based cap layers 114 can be formed over the top and bottom of the inner spacer 112 with various shapes, which can be achieved by adjusting the fabrication process. These shapes may include rectangular, triangular, trapezoidal, or elliptical configurations, depending on the desired device characteristics. In some embodiments, the profiles of the stressor EPI 1102 may include a mountain shape (as shown in FIG. 20(a)), or a convex shape (as shown in FIG. 20(b)). The GAA FET device 2000 of FIG. 20 is substantially similar to the GAA FET device 100 of FIG. 1, except for different profiles for the silicon-based cap layers 114 and the stressor EPI 1102. In some embodiments, the presence of the Si-based cap layer plays a crucial role in enhancing the stressor epitaxial (EPI) growth, resulting in an enlarged stressor region that applies additional strain to the channel. This increased strain improves carrier mobility and overall device performance. As a result of the Si cap layer, the gate-all-around (GAA) Si-sheet geometry and the stressor EPI shape are modified compared to the original GAA structure, offering opportunities to optimize the device's electrical and mechanical properties.

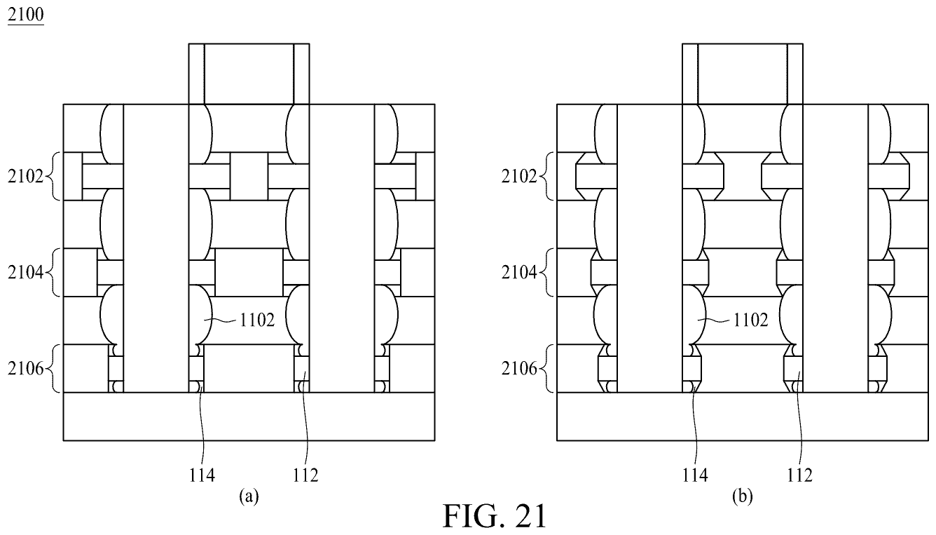

FIG. 21 illustrates a cross-sectional view of a gate-all-around (GAA) field-effect-transistor (FET) device, in accordance with some embodiments. FIG. 21 illustrates an alternative example of FIG. 1 by introducing different profiles and critical dimensions (CD) for the silicon-based cap layers 114 and different profiles the stressor EPI 1102. In some embodiments, each of the pairs of silicon-based cap layers 114 may have a pair of profiles symmetric to each other with respect to the corresponding inner spacer 112. In some embodiments, the profiles may each include a rectangle shape (as shown in FIG. 21(a)), or a trapezoid shape (as shown in FIG. 21(b)). The silicon-based cap layers 114 can be formed over the top and bottom of the inner spacer 112 with various shapes, which can be achieved by adjusting the fabrication process. These shapes may include rectangular, triangular, trapezoidal, or elliptical configurations, depending on the desired device characteristics. In some embodiments, the critical dimension (CD) of the Si cap layer exhibits a gradient reduction from top to bottom 2102, 2104, 2106 due to process loading effects, where the second Si-cap CD 2104 is about 50% to 100% of the first Si-cap CD 2102, and the third Si-cap CD 2106 is about 50% to 100% of the second Si-cap CD 2104. This gradual reduction in CD impacts the structural profile of the Si cap layer 114. In some embodiments, the profiles of the stressor EPI 1102 may include a convex CD with loading (as shown in FIG. 21(a) and 21(b)). The GAAFET device 2100 of FIG. 21 is substantially similar to the GAA FET device 100 of FIG. 1, except for different profiles and critical dimensions (CD) for the silicon-based cap layers 114 and different profiles the stressor EPI 1102. In some embodiments, the presence of the Si-based cap layer plays a crucial role in enhancing the stressor epitaxial (EPI) growth, resulting in an enlarged stressor region that applies additional strain to the channel. This increased strain improves carrier mobility and overall device performance. As a result of the Si cap layer, the gate-all-around (GAA) Si-sheet geometry and the stressor EPI shape are modified compared to the original GAA structure, offering opportunities to optimize the device's electrical and mechanical properties.

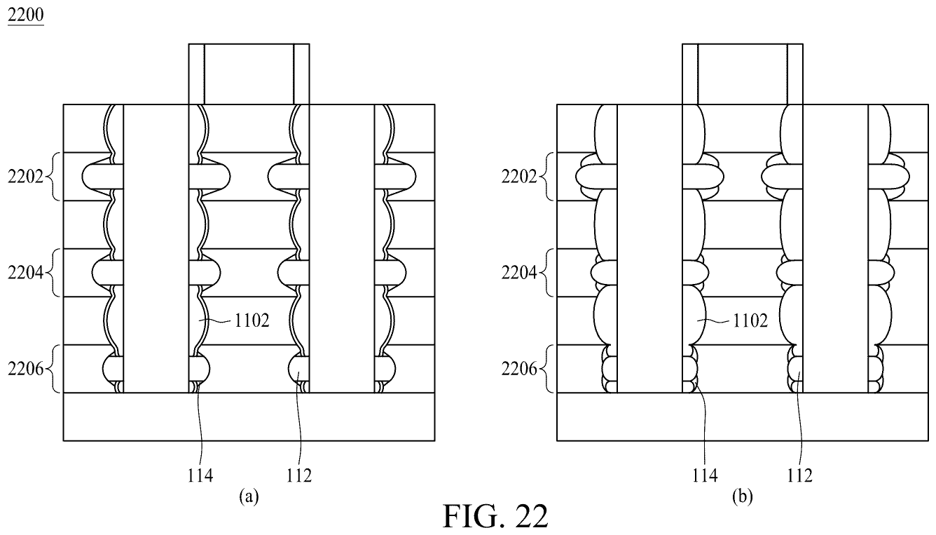

FIG. 22 illustrates a cross-sectional view of a gate-all-around (GAA) field-effect-transistor (FET) device, in accordance with some embodiments. FIG. 22 illustrates an alternative example of FIG. 1 by introducing different profiles and critical dimensions (CD) for the silicon-based cap layers 114 and different profiles the stressor EPI 1102. In some embodiments, each of the pairs of silicon-based cap layers 114 may have a pair of profiles symmetric to each other with respect to the corresponding inner spacer 112. In some embodiments, the profiles may each include a triangle shape (as shown in FIG. 22(a)), or an ellipse shape (as shown in FIG. 22(b)). The silicon-based cap layers 114 can be formed over the top and bottom of the inner spacer 112 with various shapes, which can be achieved by adjusting the fabrication process. These shapes may include rectangular, triangular, trapezoidal, or elliptical configurations, depending on the desired device characteristics. In some embodiments, the critical dimension (CD) of the Si cap layer exhibits a gradient reduction from top to bottom 2202, 2204, 2206 due to process loading effects, where the second Si-cap CD 2204 is about 50% to 100% of the first Si-cap CD 2202, and the third Si-cap CD 2206 is about 50% to 100% of the second Si-cap CD 2204. This gradual reduction in CD impacts the structural profile of the Si cap layer 114. In some embodiments, the profiles of the stressor EPI 1102 may include a mountain shape CD with loading (as shown in FIG. 22(a)), or a convex CD with loading (as shown in FIG. 22(a)). The GAA FET device 2200 of FIG. 22 is substantially similar to the GAA FET device 100 of FIG. 1, except for different profiles and critical dimensions (CD) for the silicon-based cap layers 114 and different profiles the stressor EPI 1102. In some embodiments, the presence of the Si-based cap layer plays a crucial role in enhancing the stressor epitaxial (EPI) growth, resulting in an enlarged stressor region that applies additional strain to the channel. This increased strain improves carrier mobility and overall device performance. As a result of the Si cap layer, the gate-all-around (GAA) Si-sheet geometry and the stressor EPI shape are modified compared to the original GAA structure, offering opportunities to optimize the device's electrical and mechanical properties.

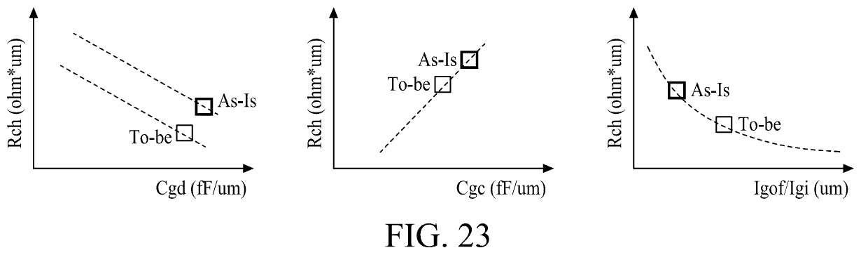

FIG. 23 illustrates an example performance of a gate-all-around (GAA) field-effect-transistor (FET) device, in accordance with some embodiments. The extent of junction push in a GAA device can be evaluated by analyzing its performance metrics, particularly the relationship between channel resistance (Rch) and key electrical parameters such as gate-to-drain capacitance (Cgd), gate-to-contact capacitance (Cgc), and gate leakage currents (Igof and Igi). The channel resistance (Rch) provides insight into the conductivity of the channel, while Cgd and Cgc reflect the capacitance between the gate and other terminal regions, indicating how the electric field interacts within the device structure. Additionally, the gate leakage current in accumulation mode (Igof) and inversion mode (Igi) provides critical information about the leakage characteristics of the MOS device under different operating conditions. A thorough evaluation of these parameters offers a comprehensive understanding of how junction push affects the electrical performance of the MOS device, enabling process and design optimization for enhanced reliability and efficiency.

In one aspect of the present disclosure, a semiconductor device is disclosed. The semiconductor device comprises a plurality of nanostructures, a first epitaxial structure, a second epitaxial structure, a gate structure, a plurality of inner spacers, and a plurality of pairs of silicon-based cap layers. The plurality of nanostructures can be vertically spaced from one another. The first epitaxial structure and a second epitaxial structure can be coupled to ends of each of the plurality of nanostructures, respectively. The gate structure wraps around each of the plurality of nanostructures. Each of the plurality of inner spacers can be interposed between a corresponding section of the gate structure and the first or second epitaxial structure. Each of the pairs of silicon-based cap layers can be disposed above and below a corresponding one of the plurality of inner spacers, respectively.

In another aspect of the present disclosure, a semiconductor device is disclosed. The semiconductor device comprises a first nanostructure, an epitaxial structure, a gate structure, a first inner spacer a first silicon-based cap layer, and a second silicon-based layer. The first nanostructure may extend along a first lateral direction. The epitaxial structure can be coupled to one end of the first nanostructure. The gate structure may extend along a second lateral direction perpendicular to the first lateral direction. The gate structure may wrap around the first nanostructure. The first inner spacer can be interposed between a first portion of the gate structure and the epitaxial structure along the first lateral direction. The first silicon-based cap layer can be in contact with a top surface of the first inner spacer and interposed between the first portion of the gate structure and the epitaxial structure along the first lateral direction. The second silicon-based cap layer can be in contact with a bottom surface of the first inner spacer and interposed between the first portion of the gate structure and the epitaxial structure along the first lateral direction.

In yet another aspect of the present disclosure, a method for fabricating semiconductor devices is disclosed. The method includes forming a stack including a plurality of first nanostructures and a plurality of second nanostructures alternately stacked on top of one another. Each of the plurality of first and second nanostructures extends along a first lateral direction. The method includes forming a first gate structure traversing the stack. The first gate structure extends along a second lateral direction perpendicular to the first lateral direction. The method includes inwardly etching end portions of each of the plurality of second nanostructures to form a plurality of recesses. The method includes forming a silicon-based cap layer lining each of the plurality of recesses. The method includes forming a plurality of inner spacers to fill the plurality of recesses, respectively. The method includes removing respective remaining portions of the plurality of second nanostructures and the first gate structure, concurrently with removing a portion of the silicon-based cap layer. The method includes forming a second gate structure wrapping around each of the plurality of first nanostructures.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a plurality of nanostructures extending along a first direction, wherein the plurality of nanostructures are disposed over and spaced from one another;
a first epitaxial structure and a second epitaxial structure coupled to ends of each of the plurality of nanostructures, respectively;
a gate structure extending along a second direction perpendicular to the first direction, wherein the gate structure wraps around each of the plurality of nanostructures;
a plurality of inner spacers, wherein each of the plurality of inner spacers is interposed between a corresponding section of the gate structure and the first or second epitaxial structure; and
a plurality of silicon-based cap layers, wherein each of the plurality of silicon-based cap layers is disposed above or below a corresponding one of the plurality of inner spacers.

2. The semiconductor device of claim 1, wherein each of the plurality of silicon-based cap layers is interposed between the corresponding section of the gate structure and the first or second epitaxial structure.

3. The semiconductor device of claim 1, wherein the plurality of silicon-based cap layers each include silicon, silicon germanium, or silicon doped with phosphorus.

4. The semiconductor device of claim 3, wherein the plurality of nanostructures includes silicon.

5. The semiconductor device of claim 1, further comprising:
a plurality of nitride layers;
wherein each of the plurality of nitride layers at least partially surrounds a corresponding one of the plurality of inner spacers.

6. The semiconductor device of claim 1, further comprising:
a plurality of stressor epitaxial structures;
wherein each of the plurality of stressor epitaxial structures is interposed between a corresponding one of the plurality of silicon-based cap layers and the first or second epitaxial structure.

7. The semiconductor device of claim 6, wherein each of the plurality of stressor epitaxial structures is further interposed between a corresponding one of the plurality of nanostructures and the first or second epitaxial structure.

8. The semiconductor device of claim 1, wherein each of the plurality of silicon-based cap layers has a first sidewall, each of the plurality of inner spacers has a second sidewall, and the first sidewall and the second sidewall are vertically aligned with each other.

9. The semiconductor device of claim 1, wherein each of the plurality of silicon-based cap layers has a first sidewall, each of the plurality of inner spacers has a second sidewall, and the first sidewall and the second sidewall are vertically offset from each other.

10. The semiconductor device of claim 1, wherein two of the plurality of silicon-based cap layers are in a pair with respect to the corresponding inner spacer, and the two of the plurality of silicon-based cap layers have profiles symmetric to each other.

11. The semiconductor device of claim 10, wherein the profiles each include a rectangular shape, a trapezoidal shape, a triangular shape, or an elliptical shape.

12. A semiconductor device, comprising:
a first nanostructure extending along a first direction;
an epitaxial structure coupled to one end of the first nanostructure;
a gate structure extending along a second direction perpendicular to the first direction, wherein the gate structure wraps around the first nanostructure;
a first inner spacer interposed between a first portion of the gate structure and the epitaxial structure along the first direction; and
a first silicon-based cap layer and a second silicon-based cap layer;
wherein the first silicon-based cap layer is in contact with a top surface of the first inner spacer, and interposed between the first portion of the gate structure and the epitaxial structure along the first direction; and
wherein the second silicon-based cap layer is in contact with a bottom surface of the first inner spacer, and interposed between the first portion of the gate structure and the epitaxial structure along the first direction.

13. The semiconductor device of claim 12, further comprising:
a second nanostructure extending along the first direction and having one end coupled to the epitaxial structure, wherein the gate structure wraps around the second nanostructure;
a second inner spacer interposed between a second portion of the gate structure and the epitaxial structure along the first direction; and
a third silicon-based cap layer and a fourth silicon-based cap layer;
wherein the third silicon-based cap layer is in contact with a top surface of the second inner spacer, and interposed between the second portion of the gate structure and the epitaxial structure along the first direction; and
wherein the fourth silicon-based cap layer is in contact with a bottom surface of the second inner spacer, and interposed between the second portion of the gate structure and the epitaxial structure along the first direction.

14. The semiconductor device of claim 13, wherein the first nanostructure and the second nanostructure are vertically spaced from each other.

15. The semiconductor device of claim 12, wherein the one end of the first nanostructure, respective sidewalls of the first and second silicon-based cap layer, and a sidewall of the first inner spacer are vertically aligned with one another.

16. The semiconductor device of claim 12, wherein the one end of the first nanostructure and a sidewall of the first inner spacer are vertically aligned with one another, with respective sidewalls of the first and second silicon-based cap layer vertically misaligned with the one end of the first nanostructure and the sidewall of the first inner spacer.

17. The semiconductor device of claim 12, wherein the first and second silicon-based cap layers each include silicon, silicon germanium, or silicon doped with phosphorus.

18. A method for fabricating semiconductor devices, comprising:
forming a stack including a plurality of first nanostructures and a plurality of second nanostructures alternately stacked on top of one another, wherein each of the plurality of first and second nanostructures extends along a first direction;
forming a first gate structure traversing the stack, wherein the first gate structure extends along a second direction perpendicular to the first direction;
inwardly etching end portions of each of the plurality of second nanostructures to form a plurality of recesses;
forming a silicon-based cap layer lining each of the plurality of recesses;
forming a plurality of inner spacers to fill the plurality of recesses, respectively;
removing respective remaining portions of the plurality of second nanostructures and the first gate structure, concurrently with removing a portion of the silicon-based cap layer; and
forming a second gate structure wrapping around each of the plurality of first nanostructures.

19. The method of claim 18, further comprising:
prior to the step of forming the plurality of inner spacers, forming a nitride layer lining the silicon-based cap layer.

20. The method of claim 18, wherein the silicon-based cap layer includes silicon, silicon germanium, or silicon doped with phosphorus.
